(19) United States
(12) Patent Application Publication
(10) Pub. No.: US 2012/0033371 A1
(43) Pub. Date: Feb. 9, 2012

(54) Display Mounting Apparatus

(75) Inventors: David Mathew Pankros, Leawood, KS (US); Lawrence Edward Guerra, Mission, KS (US)

(73) Assignee: David Mathew Pankros, Leawood, KS (US)

(21) Appl. No.: 13/197,150

(22) Filed: Aug. 3, 2011

Related U.S. Application Data
(60) Provisional application No. 61/370,945, filed on Aug. 5, 2010.

(51) Int. Cl. G06F 1/16; H05K 7/00

(52) U.S. Cl. 361/679.21; 248/231.91; 361/807

(57) ABSTRACT

A display mounting apparatus includes a wall mount, a support mechanism that includes an upper support arm rotatably disposed on the wall mount and a lower support arm rotatably disposed on the wall mount, a lift mechanism, and a display support rotatably disposed on the upper support arm and the lower support arm. The display mounting apparatus is operable to move from a retracted position to an extended position. The display support is operable to support a display weighing 15 kg or more.

### RELATED APPLICATIONS

This application claims the benefit of U.S. Provisional Application No. 60/370,945, filed Aug. 5, 2010 which is incorporated by specific reference in its entirety herein.

### FIELD OF THE INVENTION

This present invention relates to display mounts. More particularly, the invention relates to adjustable flat panel display mounts.

### BACKGROUND

Flat panel displays have become the most common type of display in homes and businesses, in part, because their thin profile allows them to be mounted on a wall. In homes, one common mounting location is above the mantel of a fireplace. In this configuration, the television can present the appearance of a piece of art, but the location is commonly several feet higher than a comfortable viewing height for a seated viewer causing neck strain and discomfort.

Prior art display mounts tilt, extend from a wall (so-called “articulating” mounts), or attach to a ceiling. No mount allows for a generally flat mount to a wall at an elevated position, such as above a mantel, and also allows for comfortable viewing for seated viewers.

Display mounts for computer monitors have allowed some degree of height adjustment, but none are suitable for displays that weigh more than approximately 11.3 kg-13.6 kg (25-30 pounds) and use manual adjustment mechanisms. Thus, they are particularly inappropriate for consumer televisions that can weigh 45 kg (100 pounds) or more.

### SUMMARY

The present invention solves the above-described problems and provides a distinct advance in the art of flat panel display mounts. More particularly, the present invention provides a flat panel display mount that extends to a height that is comfortable for a seated viewer, can extend beyond a fireplace mantel, supports the weight of the display for easy adjustment, and retracts close to a wall for a pleasing appearance, similar to a piece of hung artwork, when not in use.

One embodiment of a display mounting apparatus broadly includes a wall mount, a support mechanism, a display support, and an electronics system. The wall mount fixably secures to a wall or other element of a structure, such as a home or building. The support mechanism includes an upper support arm and a lower support arm rotatably connected at a proximal end to the wall mount. The support mechanism may also include a lift mechanism. The display support removably attaches a display to the display mounting apparatus and is rotatably attached to the upper support arm and lower support arm at their distal ends. The electronics system signals to the lift mechanism to move the display mounting apparatus to an extended position or to a retracted position after receiving an external signal, such as an infrared signal from a conventional remote control.

Another embodiment of a display mounting apparatus broadly includes a wall mount, a support mechanism, and a display support. The display support further includes a rotating mechanism for rotating a display about a substantially vertical axis.

Another embodiment of a display mounting apparatus broadly includes a wall mount, a support mechanism, and a display support. The display support further includes a rotating mechanism for rotating a display about a substantially horizontal axis.

Another embodiment of a display mounting apparatus broadly includes a wall mount, a support mechanism, and a display support. The support mechanism further includes a folding support arm to prevent drooping of the display mount when the display mounting apparatus is in an extended position.

Another embodiment of a display mounting apparatus broadly includes a wall mount, a support mechanism, and a display support. The support mechanism further includes a cam and a spring at a distal end of the upper support arm and the lower support arm and the upper support arm is attached to the display mount with an elongated arcuate slot. The superior edge of the display mount is operable to follow the cam and, thus, tilt at a predetermined angle based on the cam profile.

Another embodiment of a display mounting apparatus broadly includes a wall mount, a support mechanism, a display support, and an electronics system. The wall mount includes a proximal rotation mechanism for rotating the support mechanism about a substantially horizontal axis. The support mechanism includes a single support arm. The display support includes a distal rotation mechanism for tilting the display support about a substantially horizontal axis. The electronics system directs the proximal and distal rotation mechanisms to rotate and, thus, moves the display mounting apparatus from a retracted position to an extended position.

Another embodiment of a display mounting apparatus broadly includes a wall mount, a support mechanism, a display support, and a shroud. The shroud is a tubular structure attached at a proximal end to the wall mount and at a distal end to the display mount for concealing the support mechanism from view, reducing noise, and providing a more aesthetic appearance.

This summary is provided to introduce a selection of concepts in a simplified form that are further described below in the detailed description below. This summary is not intended to identify key features or essential features of the claimed subject matter, nor is it intended to be used to limit the scope of the claimed subject matter. Other aspects and advantages of the present invention will be apparent from the following detailed description of the embodiments and the accompanying drawing figures.

### BRIEF DESCRIPTION OF THE DRAWING FIGURES

Embodiments of the present technology are described in detail below with reference to the attached drawing figures, wherein:

FIG. 1 is an isometric view of a display mounting apparatus constructed in accordance with an embodiment of the present invention showing a flat panel display, a wall mount, a support mechanism, and a display support, the display mounting apparatus in an extended position;

FIG. 2 is an isometric view of a display mounting apparatus of FIG. 1 without the flat panel display and showing an attachment plate on the display support;

FIG. 3 is an elevation view from the top of the display mounting apparatus of FIG. 2;

FIG. 4 is an elevation view from the left side of the display mounting apparatus of FIG. 2;

FIG. 5 is an isometric view of a display mounting apparatus of FIG. 2 without the attachment plate on the display support;

FIG. 6 is an elevation view of a distal side of the support mechanism of FIG. 2;

FIG. 7 is an isometric view of the support mechanism of FIG. 2;

FIG. 8 is an elevation view of the proximal side of the display support of FIG. 2;

FIG. 9 is an isometric view of the proximal side of the attachment plate of FIG. 2;

FIG. 10 is a block diagram of an electronics system that may be used with embodiments of the present invention;

FIG. 11 is an isometric view of the display mounting apparatus of FIG. 1 in a retracted position;

FIG. 12 is an isometric view of the display mounting apparatus of FIG. 1 between an extended position and a retracted position;

FIG. 13 is an isometric view of the display mounting apparatus of FIG. 1 in an extended position;

FIG. 14 is an isometric view of a display mounting apparatus constructed in accordance with a second embodiment of the invention;

FIG. 15 is an isometric view of a display mounting apparatus constructed in accordance with a third embodiment of the invention;

FIG. 16 is an isometric view of a display mounting apparatus constructed in accordance with a fourth embodiment of the invention showing the distal side of a display support and the distal side of a wall mount;

FIG. 17 is an isometric view of the display mounting apparatus of FIG. 15 showing the proximal side of the display support and the proximal side of the wall mount;

FIG. 18 is an isometric view of a display mounting apparatus constructed in accordance with a fifth embodiment of the invention in a partially extended position;

FIG. 19 is an isometric view of the display mounting apparatus of FIG. 18 in a almost fully retracted position;

FIG. 20 is an isometric view of a display mounting apparatus constructed in accordance with a sixth embodiment of the invention showing the distal side of a display support and the distal side of a wall mount;

FIG. 21 is an isometric view of the display mounting apparatus of FIG. 20 showing the proximal side of a display support and the proximal side of a wall mount; and

FIG. 22 is an isometric view of a display mounting apparatus constructed in accordance with a seventh embodiment of the invention.

The drawing figures do not limit the present invention to the specific embodiments disclosed and described herein. The drawings are not necessarily to scale, emphasis instead being placed upon clearly illustrating the principles of the technology.

### DETAILED DESCRIPTION

The following detailed description of various embodiments of the present technology references the accompanying drawings which illustrate specific embodiments in which the technology can be practiced. The embodiments are intended to describe aspects of the technology in sufficient detail to enable those skilled in the art to practice them. Other embodiments can be utilized and changes can be made without departing from the scope of the technology. The following detailed description is, therefore, not to be taken in a limiting sense. The scope of the present technology is defined only by the appended claims, along with the full scope of equivalents to which such claims are entitled.

Note that in this description, references to “one embodiment” or “an embodiment” mean that the feature being referred to is included in at least one embodiment of the present invention. Further, separate references to “one embodiment” or “an embodiment” in this description do not necessarily refer to the same embodiment; however, such embodiments are also not mutually exclusive unless so stated, and except as will be readily apparent to those skilled in the art from the description. For example, a feature, structure, act, etc. described in one embodiment may also be included in other embodiments. Thus, the present invention can include a variety of combinations and/or integrations of the embodiments described herein.

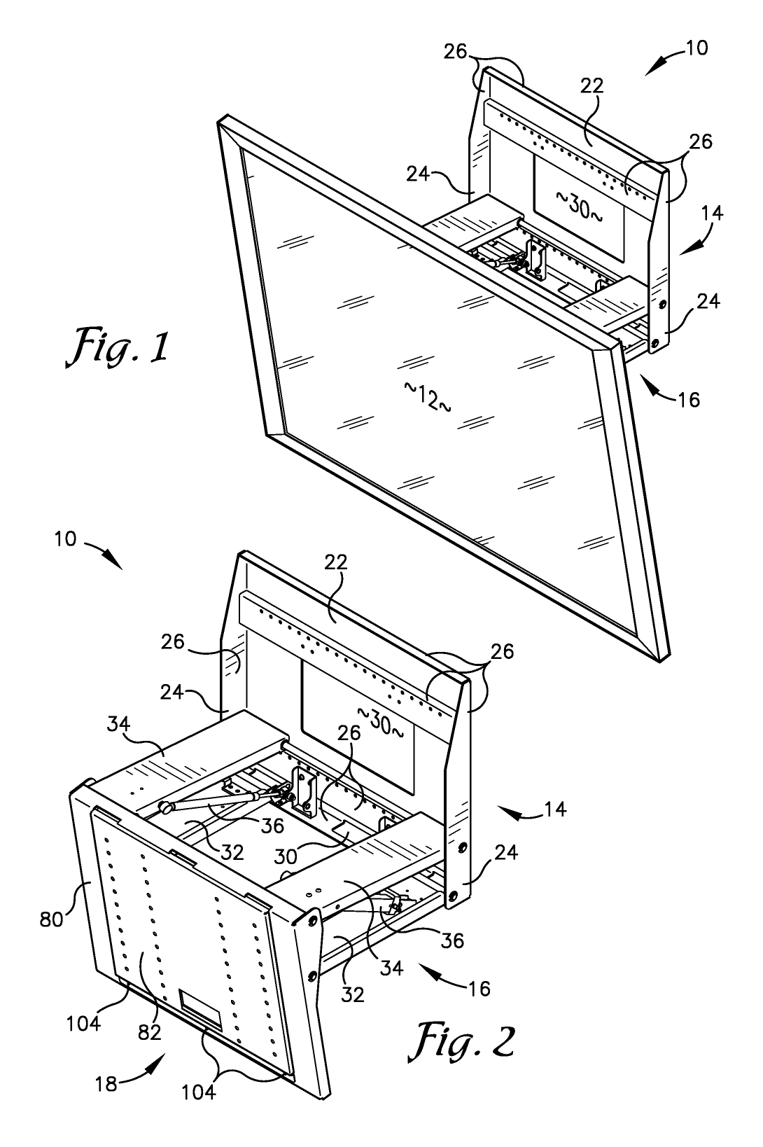

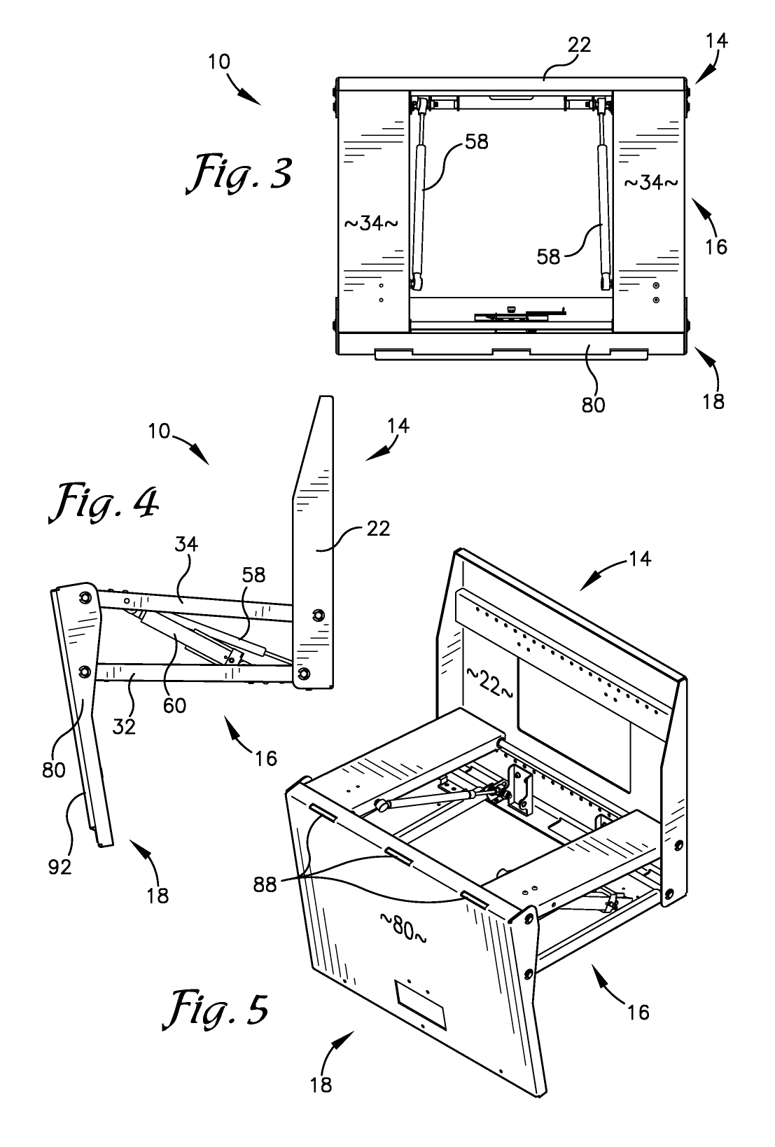

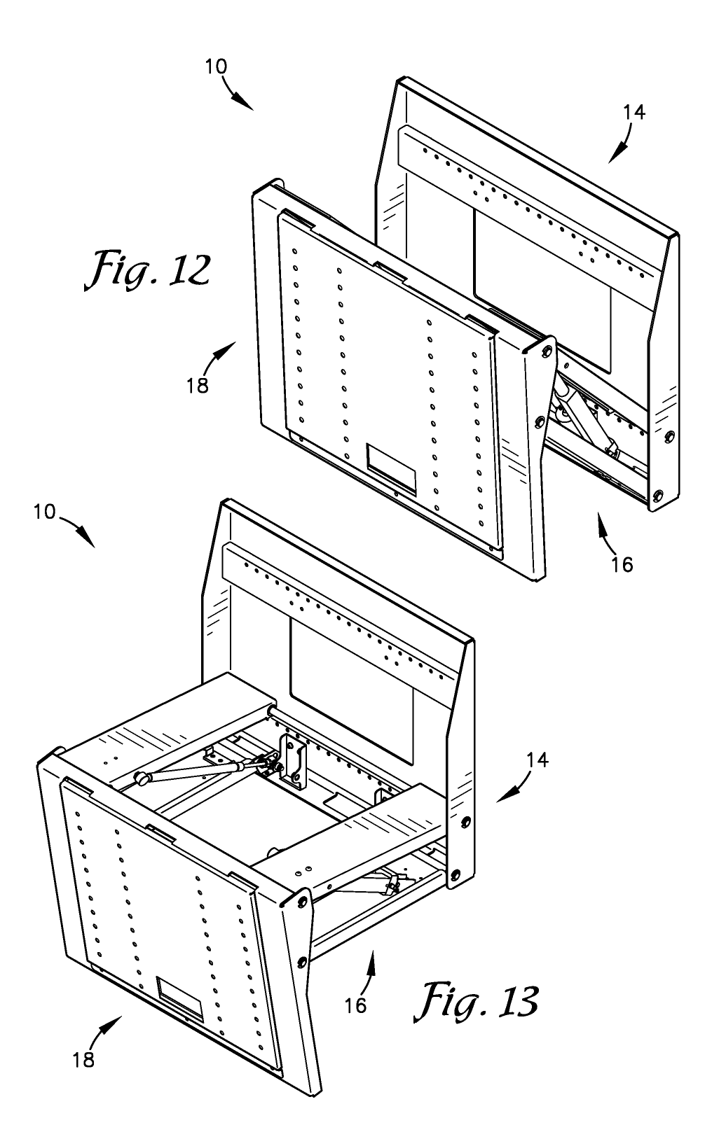

Turning now to the drawing figures and, in particular, FIGS. 1-13, a display mounting apparatus 10 for a flat panel display 12 is illustrated and broadly comprises a wall mount 14, a support mechanism 16, a display support 18, and an electronics system 20.

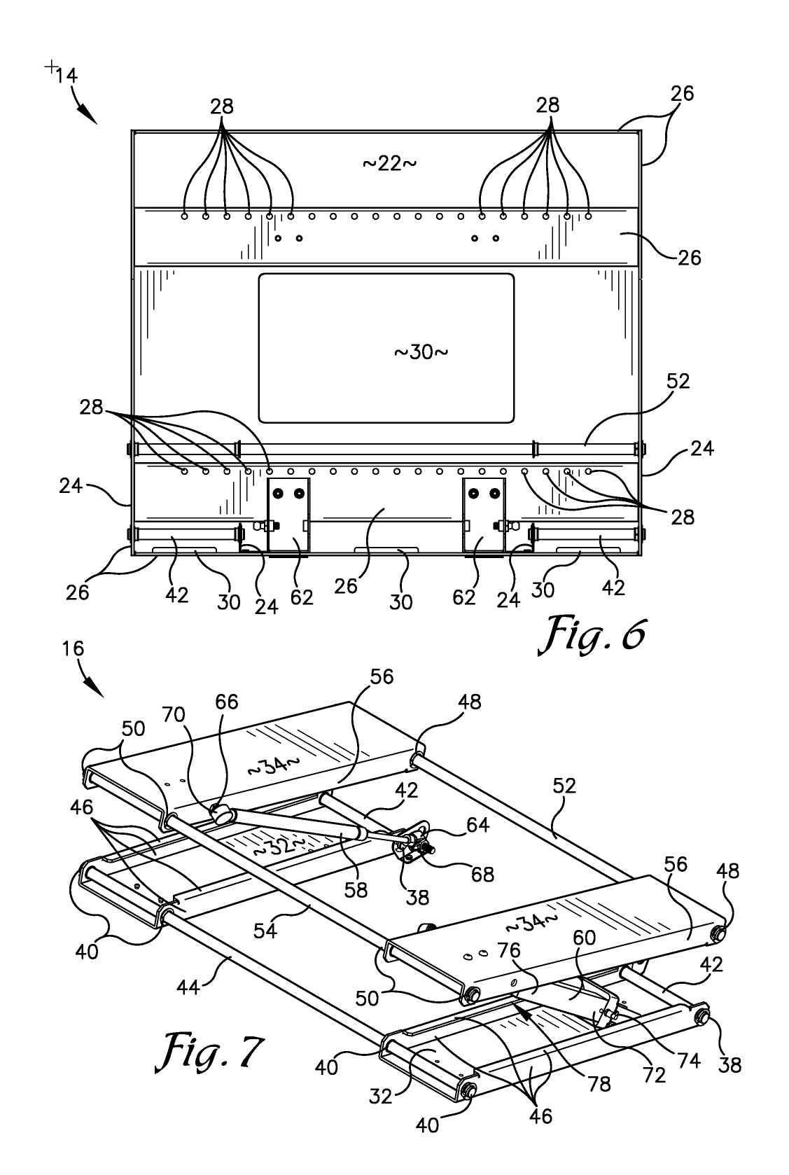

Turning particularly to FIG. 6, the wall mount 14 generally includes a main body 22 and attachment features 24, and reinforcing features 26. The wall mount 14 may be fabricated from steel, aluminum, an alloy, a composite material, or the like. In various embodiments, the wall mount 14 may be formed from a single piece of material. In other embodiments, the main body 22 and the attachment features 24 may be separately formed and attached with welds, fasteners, adhesive, or the like.

The main body 22 is generally planar and securely attaches the display mounting apparatus 10 to a wall or other fixed surface. In this embodiment, the main body 22 is generally rectangular, but the main body 22 may be any shape. Additionally, the main body 22 may include a plurality of attachment holes 28 distributed at various points along its surface for attaching the wall mount 14 to a wall or fixed surface with fasteners such as screws, bolts, pins, lugs, or the like. In this embodiment, the plurality of attachment holes 28 are arranged in substantially horizontal rows where each of the attachment holes 28 is uniformly spaced from each of its neighboring attachment holes 28. The spacing between adjacent attachment holes 28 may be 1.27 cm (0.5 inch), 2.54 cm (1 inch), 5.08 cm (2 inches), or any other spacing as needed under the circumstances. Thus, the attachment holes 28 facilitate securely anchoring the wall mount 14 into regularly spaced wall studs, or the like. In other embodiments, the attachment holes 28 may be horizontally or vertically extended slots to facilitate adjustment of the display mounting apparatus 10 while enabling the fasteners to secure into wall studs, masonry, anchors, or the like, contained within the wall of a building or structure. In some embodiments, the main body 22 may further include an aperture 30 therein to facilitate cables to be passed through.

The attachment features 24 facilitate attaching the support mechanism 16 to the wall mount 14 and may comprise flanges, raised knuckles, raised portions of the main body 22, or the like. In some embodiments, the attachment features 24 may include a plurality of spaced-apart flanges with a pin-receiving hole therethrough, like a clevis. The attachment features 24 may be formed integrally with the wall mount 14 or the reinforcing features 26, or may be separately formed and secured thereto with welds, adhesives, screws, bolts, or the like.

In some embodiments, the reinforcing features 26 support, or are integrated with, the attachment features 24 or improve the rigidity or strength of the wall mount 14. The reinforcing features 26 may comprise raised knuckles, raised portions of the main body 22, cut-out portions of the main body 22, flanges, fluted portions, rounded portions, or various other structures that increase the strength or rigidity of the wall mount 14. The reinforcing features 26 may be formed integrally with the wall mount 14 or the attachment features 24, or may be separately formed and secured thereto with welds, adhesives, screws, bolts, or the like.

Turning particularly to FIG. 7, the support mechanism 16 pivotally connects the display support 18 to the wall mount 14 and includes a lower support arm 32, an upper support arm 34 and, in some embodiments, the support mechanism 16 may further include a lift mechanism 36.

The lower support arm 32 may be fabricated from various metals, alloys, composite materials, or the like. The lower support arm 32 includes a proximal attachment point 38 at a proximal end of the lower support arm 32 and a distal attachment point 40 at a distal end of the lower support arm 32. Each lower support arm 32 is pivotally connected at the proximal attachment point 38 to a corresponding attachment feature 24 of the main body 22 with a fastener 42 such as bolts, pins, screws, lugs, or the like. Correspondingly, the lower support arm 32 is pivotally connected at the distal attachment point 40 to the display support 18 with a fastener 44 such as bolts, pins, screws, lugs, or the like. In some embodiments, the lower support arm 32 may further include a reinforcing structure 46 to improve the rigidity or strength of the lower support arm 32.

The upper support arm 34 may be fabricated from various metals, alloys, composite materials, or the like. The upper support arm 34 includes a proximal attachment point 48 at a proximal end of the upper support arm 34 and a distal attachment point 50 at a distal end of the upper support arm 34. Each upper support arm 34 is pivotally connected at the proximal attachment point 48 to a corresponding attachment feature 24 of the main body 22 with a fastener 52 such as bolts, pins, screws, lugs, or the like. Correspondingly, each upper support arm 34 is pivotally connected at the distal attachment point 50 to the display support 18 with a fastener 54 such as bolts, pins, screws, lugs, or the like. In some embodiments, the upper support arm 34 may further include a reinforcing structure 56 to improve the rigidity or strength of the upper support arm 34. The upper support arm 34 may be the same length as the lower support arm 32 or it may be a different length.

In this embodiment, the lift mechanism 36 further comprises a weight balancing device 58 and an actuator 60.

The weight balancing device 58 connects the support mechanism 16 to a lift attachment feature 62 that is removably secured to the wall mount 14 with screws, bolts, flanges, or the like. The weight balancing device 58 includes a first attachment point 64 and a second attachment point 66 at its distal ends. The first attachment point 64 connects the weight balancing device 58 to the lift attachment feature 62 with a fastener 68, such as a bolt, a screw, a pin, a lug, ball joint, or the like, and the second attachment point 66 connects the weight balancing device 58 to the support mechanism 16 with a fastener 70, such as a bolt, a screw, a pin, a lug, ball joint, or the like. The weight balancing device 58 may be a linear actuator, a gas spring, an air spring, an extension spring, a safety drawbar spring, a torsion spring, a polymeric band, or the like. In some embodiments, the weight balancing device 58 exerts a force on the support mechanism that substantially offsets a force of gravity exerted on the display support 18 by a flat panel display 12. In some embodiments the weight balancing device 58 exerts a greater force greater than the force required to offset the force of gravity on the display support, and in others the weight balancing device 58 exerts less force.

The actuator 60 connects the upper support arm 34 to the lower support arm 32 for electronically controlling the position of the display support 18 with respect to the wall mount 14. In this embodiment, the actuator 60 is rotatably secured at a first end 72 to the lower support arm 32 with a fastener 74 such as a screw, a pin, a lug, ball joint, or the like. The actuator 60 is rotatably secured at a second end 76 to the upper support arm 34 with a fastener 78 such as a screw, a pin, a lug, ball joint, or the like.

In some embodiments, the first attachment point 64 of the weight balancing device 58 connects the support mechanism 16 to a first location on the support mechanism 16 and the second attachment point 66 connects the weight balancing device 58 to a second location on the support mechanism 16. For example, the first attachment point 64 may connect to a proximal portion of the lower support arm 32 and the second attachment point 66 may connect to a distal portion of the upper support arm 34. In yet other embodiments, the first attachment point 64 connects to the support mechanism 16 and the second attachment point 66 connects to the display support 18. In still other embodiments, the first attachment point 64 may connect to the wall mount 14 and the second attachment point 66 may connect to the display support 18.

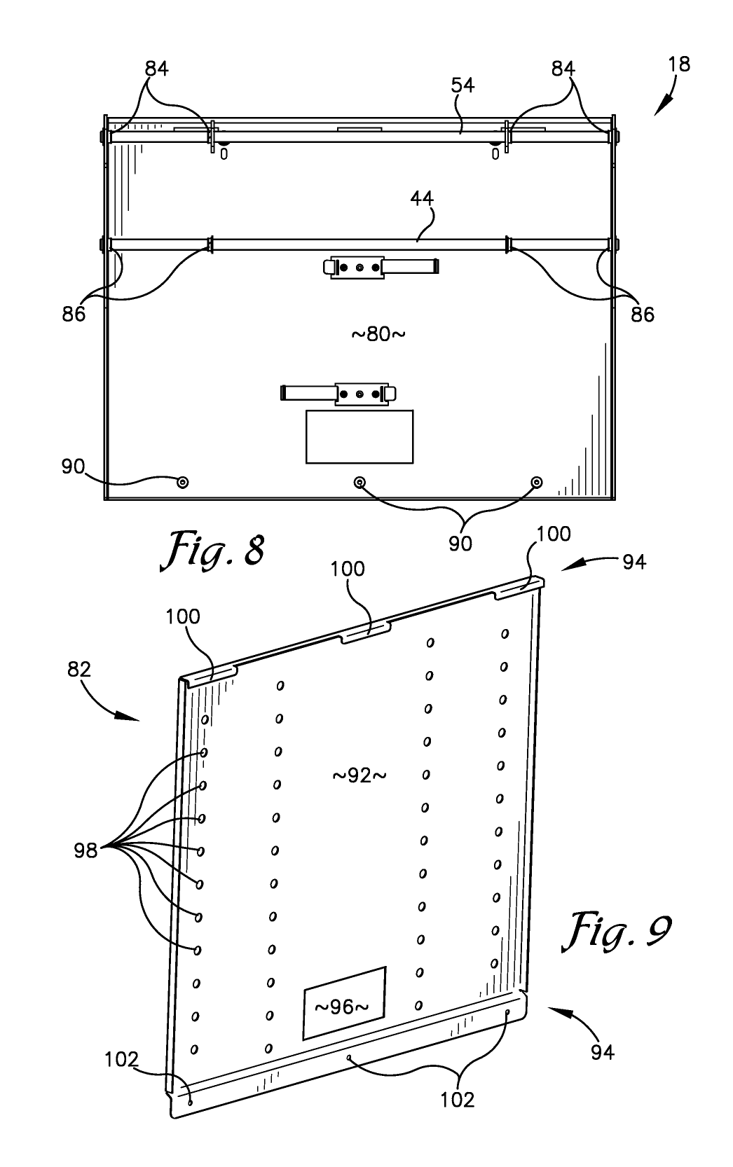

Turning particularly to FIGS. 8 and 9, the display support 18 provides a secure attachment point for the flat panel display 12 and broadly includes a main body 80, and a display attachment mechanism 82.

The main body 80 is generally planar, supports, and further includes an upper support arm attachment point 84, a lower support arm attachment point 86 and, in some embodiments, a securing device aperture 88 and a hole 90. The main body 80 may be fabricated from various metals, alloys, composite material, or the like. In some embodiments, the main body 80 is separately formed from the upper support arm attachment point 84, the lower support arm attachment point 86 and attached with welds, fasteners, adhesive, or the like.

The upper support arm attachment point 84 pivotally connects the distal attachment point 50 of the upper support arm 34 to the main body 80 of the display support 18 with a fastener 54 such as a pin, screw, lug, bolt, ball-joint, or the like. The lower support arm attachment point 86 pivotally connects the distal attachment point 40 of the lower support arm 32 to the main body 80 of the display support 18 with a fastener 44 such as a pin, screw, lug, bolt, ball-joint, or the like.

The display attachment mechanism 82 removably attaches the display 12 to the display support 18 and broadly comprises an attachment plate 92 and, in some embodiments, a securing mechanism 94.

The attachment plate 92 is generally planar and further comprises a cable-routing aperture 96, and a plurality of attachment holes 98 for removably attaching to a rear portion of the display 12 with fasteners such as screws, bolts, lugs, pins, or the like. In some embodiments, the attachment plate 92 may utilize spacers, stand-offs, washers, or the like, to extend the rear portion of the display 12 away from the attachment plate 92. The attachment plate 92 may be fabricated from various metals, alloys, composite materials, or the like.

The securing mechanism 94 removably secures the attachment plate 92 to the main body 80. In this embodiment, the securing mechanism includes a downward-facing flange 100 at the superior edge of the attachment plate 92, and a hole 102. The flange 100 enables the attachment plate to be slid over and down onto the main body 80 so the flange 100 matingly engages the aperture 88 and, thus, the attachment plate 92 may hang in place on the distal face of the main body 80. The hole 102, when the attachment plate 92 is in hanging on the main body 80, is axially aligned with the hole 90 and, thus, a fastener 104 is operable to pass through the hole 90. The fastener 104 may then be secured, removably attaching the attachment plate 92 to the main body 80.

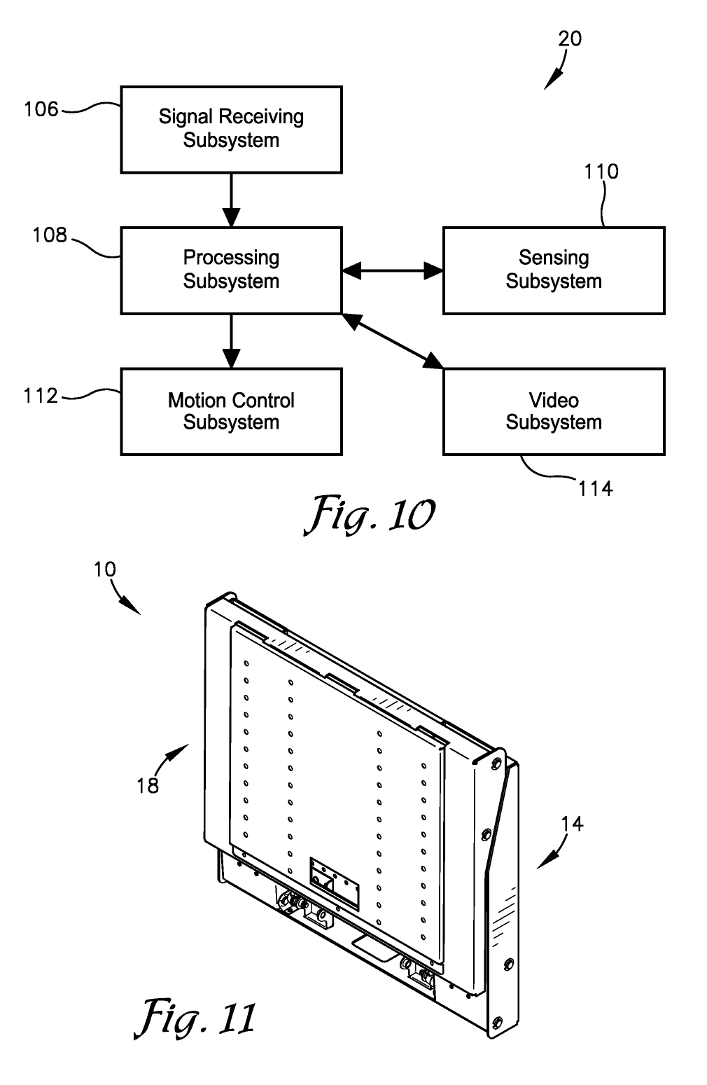

Turning to FIG. 10, the display mounting apparatus 10 may be equipped with an electronics system 20 that controls the position of the display support 18 relative to the wall mount 14 and broadly comprises a signal receiving subsystem 106, a processing subsystem 108, a sensing subsystem 110, a motion-control subsystem 112, and a video subsystem 114. The various subsystems may be separate or combined, and may utilize or share data between subsystems.

The signal receiving subsystem 106 is operable to determine if an external signal is present. The external signal may be infrared (IR), 802.11 Wi-Fi, Bluetooth, Radio Frequency (RF), 802.3 Ethernet, RS-232 Serial, USB, a DC voltage pulse, a DC voltage, or any other method of electronically signaling and/or protocol for interpreting a signal. The signal receiving subsystem may further include electronic components operable to receive and interpret the external signal. In one embodiment, the signal receiving subsystem includes an IR receiver, such as the TSOP853 from Vishay Semiconductors®. Thus, the signal receiving subsystem 106 can detect the presence of an IR command that can be used to retract or extend the display mounting apparatus 10, for example. In some embodiments, the signal receiving subsystem 106 may interface with a home automation system such as Crestron®, AMX®, Z-Wave®, Insteon®, Control 4®, or the like. When the signal receiving subsystem 106 receives an appropriate signal from the home automation system, the control subsystem can signal the motion-control 112 subsystem to move the display mounting apparatus appropriately.

The processing subsystem 108 interprets and executes commands stored on a computer-readable medium. Some embodiments of the processing subsystem 108 may utilize a computer processor such as a central processing unit (CPU), microprocessor unit (MPU), field-programmable gate array (FPGA), application specific integrated circuit (ASIC), or the like, to control various subsystems, such as the motion-control subsystem 112, the sensing subsystem 110, or the like. The processing subsystem 108 may include a computer readable medium such as FLASH memory, EEPROM, a solid state drive, RAM, or the like.

The sensing susbsystem 110 detects the environment or the position of the display mounting apparatus 10 so the processing subsystem 108 can execute a particular action. In some embodiments, the sensing subsystem 110 may utilize an accelerometer, a temperature sensor, a humidity sensor, a button, a potentiometer, a force sensor, a reed switch, a mechanical switch, a rotary position sensor, a rotary encoder, a capacitive sensor, an optical encoder, an ultrasonic rangefinder, a flex sensor, a barometric pressure sensor, or the like, or a combination thereof. In some embodiments, a video camera may be connected to the sensing subsystem 110 to move the display mounting apparatus to a retracted position when a user makes a first predetermined movement. Similarly, the display mounting apparatus may move to an extended position when a user makes a second predetermined movement.

In some embodiments, the sensing subsystem 110 may monitor for certain conditions, such as heat, humidity, or pressure. The processing subsystem 110 may then signal the motion-control subsystem 112 to adjust the position of the display mounting apparatus 10. For example, if the display mounting apparatus 10 is located over a fireplace mantel, extreme heat from a fire may damage the sensitive electronics of the flat panel display 12. A temperature sensor placed on an inferior edge of the display mounting apparatus 10 may sense a temperature over a predetermined temperature threshold and signal to the motion-control subsystem 108 to retract the display mount to avoid damage to the flat panel display 12 caused by heat. In another example, embodiments of the present invention may be used on an outdoor patio. If a water or humidity sensor placed on an upper edge of the display mounting apparatus 10 senses water, elevated humidity, or barometric pressure changes consistent with precipitation, the sensing subsystem 110 may cause the processing subsystem 108 to signal the motion-control subsystem 110 to retract the display mounting apparatus 10, and thus the display 12, to minimize the chance of damage due to water. In yet another example, a pressure or contact sensor may be placed at various points around the display mounting apparatus 10 and/or flat panel display 12 to avoid incidental contact with objects or people in the immediate vicinity of the display mounting apparatus 10. When retracting, the pressure or contact sensor may detect an object behind the display or display mount and signal to the positioning subsystem to stop retracting or to extending. Various other monitoring is also possible.

The motion-control subsystem 112 may utilize a high-current driving circuit, such as an H-bridge, or the like, to control the actuator 60. In some embodiments, the motion-control subsystem 112 may be operable to adjust the speed of the actuator by pulse-width modulation (PWM), delta-sigma modulation, pulse-amplitude modulation (PAM), pulse-code modulation (PCM), pulse-density modulation (PCM), pulse-position modulation (PPM), frequency modulation (FM), amplitude modulation (AM), or the like, and as dictated by the circuit. Thus, the motion-control subsystem 112 can cause the lift mechanism 36 to extend the display mounting apparatus 10 or retract the display mounting apparatus 10. When combined with data provided from the sensing subsystem 110, the processing subsystem 108 can direct the motion-control subsystem 112 to change behavior based on the position of the display mounting apparatus 10. For example, the processing subsystem 108 may direct the motion-control subsystem to reduce the speed of the actuator 60 when the lower support arm 32 or upper arm 34 is near a fully retracted position or near a fully extended position.

The video subsystem 114 can alter an external video signal, switch between several video signals, or generate a video signal. In one embodiment, the video subsystem 114 includes a plurality of inputs and a single output and the video subsystem 114 is operable to output a first signal from a first video input on the video output when the display mounting apparatus 10 is in a retracted position and is operable to output a second signal from a second video input on the video output when the display mounting apparatus 10 is in an extended position. Thus, the display mounting apparatus 10 may display family photos when retracted, and over-the-air (OTA) television when extended, for example. Additionally, the video subsystem may be operable to display text or an image on the flat panel display 12 when the display mounting apparatus 10 is extending or retracting. Alternatively, it may superimpose a warning over a video signal when the display mounting apparatus 10 is extending or retracting.

Turning to FIGS. 11-13, in use, the display mounting apparatus 10 is attached to a wall of a structure with one or more fasteners and the attachment plate 92 is attached to the rear side of a display 12 with one or more fasteners. The flange 100 of the securing mechanism 94 is positioned over the aperture 88 on the distal side of the main body 80 and the fastener 104 is placed through the hole 102 and hole 90 to the proximal side of the main body 80. The fastener 104 may then be secured with a nut, or the like. Thus, the display 12 is removably secured to the display mounting apparatus 10.

A user signals for the display mounting apparatus 10 to extend by pressing a button on a conventional infrared remote control, home automation system, or the like. The signal receiving subsystem 106 receives the signal. The processing subsystem 108 directs the motion-control subsystem 112 to extend or retract the actuator 60. Because the weight balancing device 58 supports the weight of the display 12, the actuator is operable to change the position of the display mounting apparatus 10 using only a minimal amount of force. As the length of the actuator 60 decreases, the support mechanism 16 rotates from a substantially vertical position at 0-degree extension, to a substantially horizontal position at 90-degree extension, or to a downward-tilting position at 120-degree extension. The sensing subsystem 110 utilizes a multi-axis accelerometer to determine the position of the support mechanism 16. Thus, at a substantially vertical position the processing subsystem 108 directs the motion-control subsystem 112 move slowly. As the support mechanism rotates away from a substantially vertical position, the processing subsystem 108 directs the motion-control subsystem 112 to accelerate to a faster speed. As the support mechanism rotates near to its target extended position, the processing subsystem 108 directs the motion-control subsystem 112 to decelerate to a slow speed. At the target position, the processing subsystem 108 directs the motion-control subsystem 112 to stop.

The display mounting apparatus 10 may be retracted using substantially the reverse steps.

Because the length of the upper support arm 34 and the lower support arm 32 are unequal and because the proximal attachment points 38, 48 and distal attachment points 40, 50 are not necessarily parallel to the wall mount 14 or to the display support 18, the display support 18 can be parallel with the wall mount 14 at a retracted position and the display support 18 can be tilted downward at a fully-extended position. Various angles and tilts can be accomplished by adjusting the length of the upper support arm 34 and the lower support arm 32, as well as by changing the location of the proximal attachment points 38, 48 and distal attachment points 40, 50.

Thus, the display mounting apparatus 10 may be extended to lower the display 12 to use the display at a comfortable viewing height and may be retracted when the display 12 is not in use. For example, the display mounting apparatus 10 may be attached over a mantel of a fireplace to provide an improved viewing angle, and prevent neck fatigue, when extended and provide attractive positioning when retracted. The display 12 may be further fitted with a decorative frame around its peripheral edge to provide the appearance of hanging artwork when the display mounting apparatus 10 is retracted.

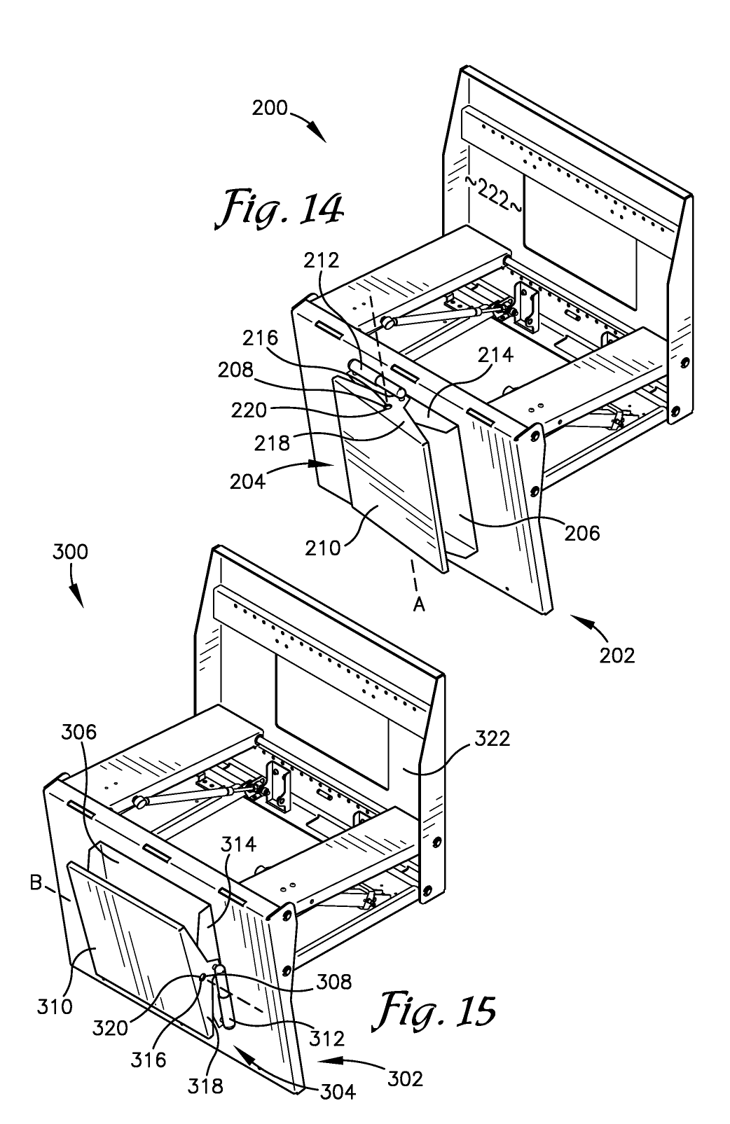

FIG. 14 illustrates another embodiment of a display mounting apparatus 200. This embodiment is substantially similar to the embodiment described with reference to FIGS. 1-13, except as indicated. In this embodiment, the display support 202 further includes a rotating mechanism 204 for rotating a display about a substantially vertical axis. The rotating mechanism 204 includes a base 206, a pivot 208, a rotating plate 210, and an actuator 212.

The base is 206 is generally planar with upstanding flanges 214 at its superior and inferior edges and is operable to receive an attachment plate thereon, such as attachment plate 92 of FIGS. 1-13. Each of the upstanding flanges 214 further includes a pin-receiving hole 216 therethrough.

The pivot 208 is generally cylindrical and enables the rotating plate 210 to rotate about the longitudinal axis of the pivot 208. In this embodiment, the pivot 208 is a pin, but in other embodiments, the pivot 208 may be a lug, a bolt, a bearing, a bushing, or the like.

The rotating plate 210 is generally planar with a flange 218 along its peripheral edge for supporting a display attachment mechanism thereon. The flanges 218 on the superior and inferior sides of the rotating plate 210 further include a pin-receiving hole 220 for receiving the pivot 208 therethrough. Thus, each pin-receiving hole 216, the pivot 208, and each pin-receiving hole 220 are axially aligned and allow the rotating plate to rotate about an axis A.

The actuator 212 is pivotally attached to the flange 218 of the rotating plate 210 and the base 206 to electromechanically pivot the rotating plate around the axis A. In this embodiment, the actuator is a linear electromechanical actuator but, in various embodiments, the actuator 212 may be a motor, a stepper motor, or various other devices capable of rotating the rotating plate 210 about the axis A.

In use, embodiments of display mounting apparatus 200, further enable a display to pivot when the display mounting apparatus is in an extended position and to return to a position parallel to a wall mount 222.

FIG. 15 illustrates another embodiment of a display mounting apparatus 300. This embodiment is substantially similar to the embodiment described with reference to FIGS. 1-13, except as indicated. In this embodiment, the display support 302 further includes a rotating mechanism 304 for rotating a display about a substantially horizontal axis. The rotating mechanism 304 includes a base 306, a pivot 308, a rotating plate 310, and an actuator 312.

The base is 306 is generally planar with upstanding flanges 314 at its lateral edges and is operable to receive an attachment plate thereon, such as attachment plate 92 of FIGS. 1-13. Each of the upstanding flanges 314 further includes a pin-receiving hole 316 therethrough.

The pivot 308 is generally cylindrical and enables the rotating plate 310 to rotate about the longitudinal axis of the pivot 308. In this embodiment, the pivot 308 is a pin, but in other embodiments, the pivot 308 may be a lug, a bolt, a bearing, a bushing, or the like.

The rotating plate 310 is generally planar with an upstanding flange 318 along its peripheral edge for supporting a display attachment mechanism thereon. The upstanding flanges 318 on the lateral sides of the rotating plate 310 further include a pin-receiving hole 320 for receiving the pivot 306 therethrough. Thus, each pin-receiving hole 316, the pivot 308, and each pin-receiving hole 320 are axially aligned and allow the rotating plate to rotate about an axis B.

The actuator 312 is pivotally attached to the upstanding flange 318 of the rotating plate 310 and the base 306 to electromechanically pivot the rotating plate around the axis B. In this embodiment, the actuator is a linear electromechanical actuator but, in various embodiments, the actuator 312 may be a motor, a stepper motor, or various other devices capable of rotating the rotating plate 310 about the axis B.

In use, embodiments of display mounting apparatus 300, further enable a display to pivot when the display mounting apparatus is in an extended position and to return to a position parallel to a wall mount 322.

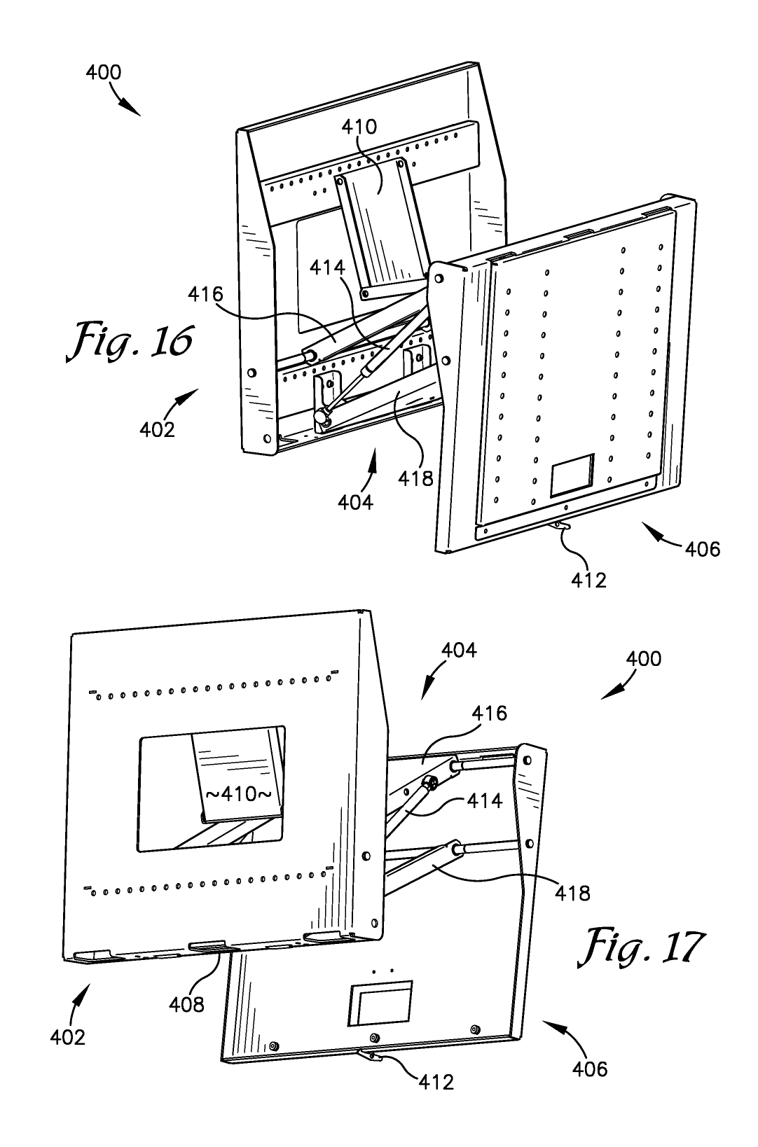

Turning now to FIGS. 16 & 17, another embodiment of the present invention is illustrated. This embodiment is substantially similar to the embodiment described with reference to FIGS. 1-13, except as indicated. The display mounting apparatus 400 broadly comprises a wall mount 402, a support mechanism 404, and a display support 406.

The wall mount 402 includes a latch receiver 408 for securing the display support 406 to the wall mount 402 when the display mounting apparatus 400 is in a retracted position.

The support mechanism 404 includes a folding support arm 410 for supporting the display support 406 when in an extended position and to prevent drooping of the display support 406 over the life of the display mounting apparatus 400.

The display support 406 includes a latch 412 for matingly engaging the latch receiver 408 and for securing the display support 406 to the wall mount 402 when the display mounting apparatus 400 is in a retracted position.

In use, embodiments of the display mounting apparatus 400 enable a user to position the display mounting apparatus without the use of an actuator or other electronic positioning device. When the display mounting apparatus 400 is in an extended position, the weight balancing device 414 exerts a force on the support mechanism 404 that causes the display support 406 to have an upward force exerted on it that is slightly less than the force of gravity on a display. Thus, in an extended position, a user needs to lift the display slightly to cause the display mounting apparatus 400 to transition from an extended position to a refracted position. In one embodiment, the display mounting apparatus 400 requires approximately 22 newtons (5 pounds) of force to begin to transition the display mounting apparatus 400 from an extended position to a retracted position. In other embodiments, the display mounting apparatus 400 requires approximately 44 newtons (10 pounds) of force to begin to transition the display mounting apparatus 400 from an extended position to a refracted position.

Because of the orientation of the weight balancing device 414, the upper support arm 416, and the lower support arm 418, in a retracted position the weight balancing device 414 exerts an upward force on the support mechanism 404 that causes the force on the display support 406 to be greater than the force of gravity. Thus, the display mounting apparatus 400 will stay in a retracted position until the user pulls on the display or display support 406. In one embodiment, the display mounting apparatus 400 requires approximately 22 newtons (5 pounds) of force to begin to transition the display mounting apparatus 400 from a retracted position to an extended position. In other embodiments, the display mounting apparatus 400 requires approximately 44 newtons (10 pounds) of force to begin to transition the display mounting apparatus 400 from a retracted position to an extended position.

Additionally, in a retracted position, the latch 412 matingly engages the latch receiver 408 and secures the display mounting apparatus 400 in a retracted position. To extend the display mounting apparatus 400, the user must disengage the latch 412 and pull on the display support 406 or on the display.

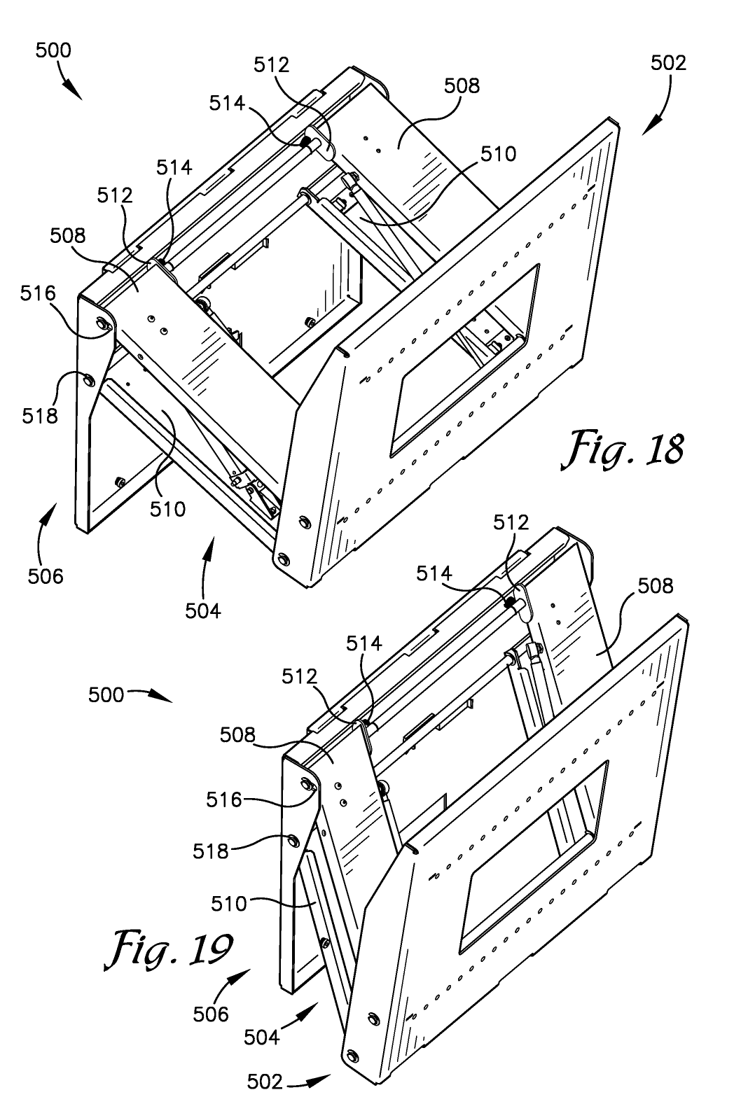

Turning now to FIGS. 18 & 19, yet another embodiment of the present invention is illustrated. This embodiment is substantially similar to the embodiment described with reference to FIGS. 1-13, except as indicated. The display mounting apparatus 500 broadly comprises a wall mount 502, a support mechanism 504, and a display support 506.

The support mechanism includes and upper support arm 508 and a lower support arm 510. The upper support arm 508 further includes a cam 512 and a spring 514 at its distal end. Additionally, the upper support arm attachment point 516 is an elongated arcutate slot. The lower support arm 510 includes a lower support arm attachment point 518 at its distal end. The cam 512 is held in position so that its longitudinal axis is parallel to the longitudinal axis of the upper support arm 508.

In use, the display support 506 is held against the cam 512 by spring 514 and pivots around the lower support arm attachment point 518. That is, the superior edge of the display support 506 is in a cam-following arrangement. As the display mounting apparatus 500 is extended and retracted the display support is operable to tilt around an axis defined by the lower support arm attachment points 518, as dictated by the shape of the cam 512.

Additionally, cam 512 is operable to be changed as desired. For example, one cam may be operable to position the display support 506 in a parallel orientation with regard to the wall mount 502 when retracted and to position the display support 506 in a 5 degree forward tilt when the display mounting apparatus 500 is extended position. Another cam may be operable to position the display support 506 in a 10 degree forward tilt when the display mounting apparatus 500 is in an extended position.

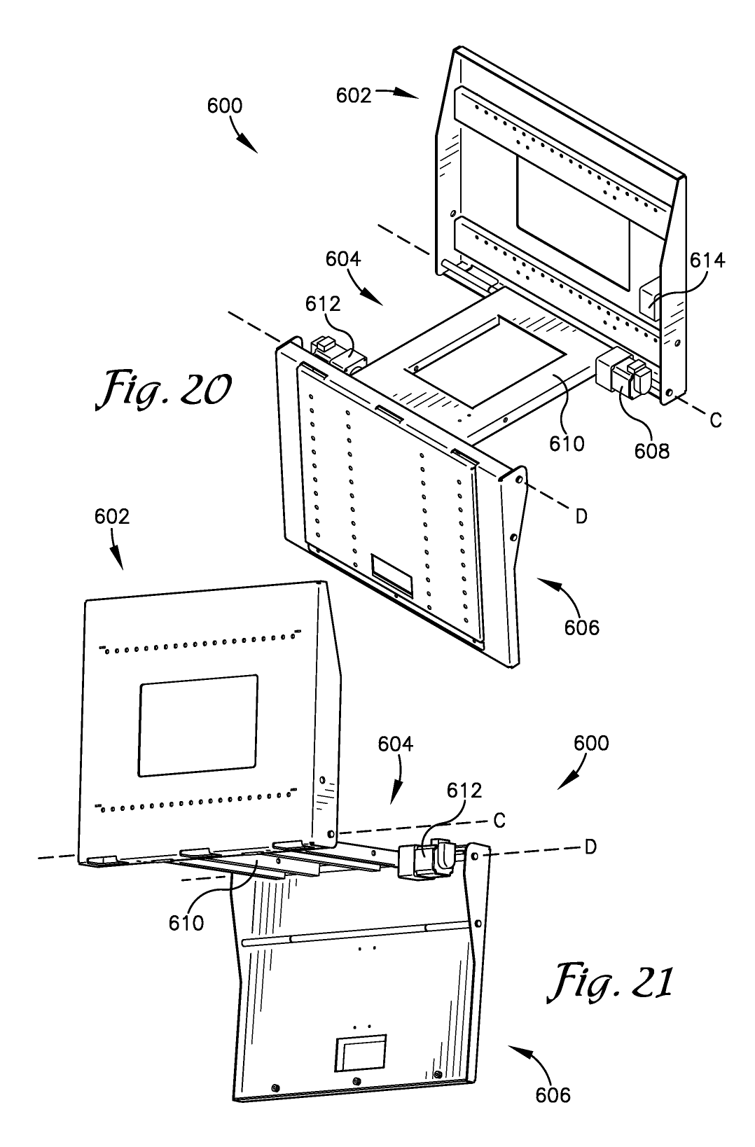

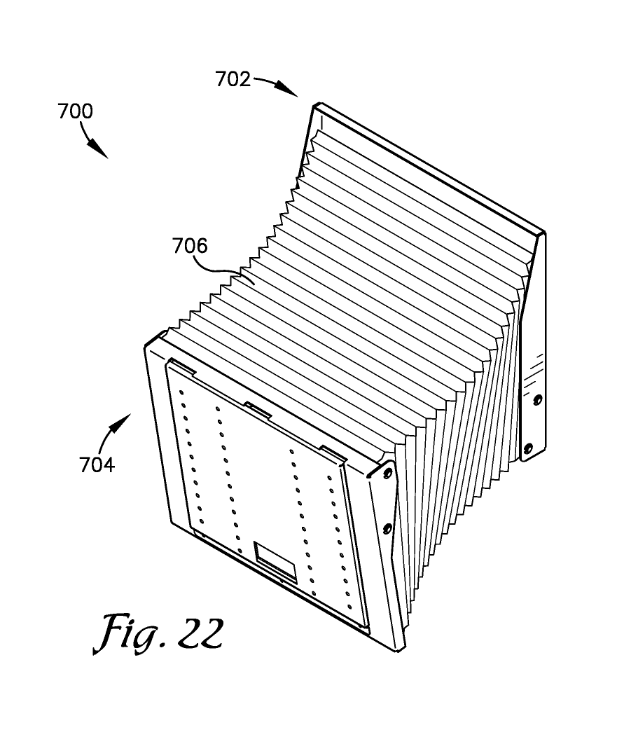

FIGS. 20 & 21 illustrate still another embodiment of the present invention. This embodiment is substantially similar to the embodiment described with reference to FIGS. 1-13, except as indicated. The display mounting apparatus 600 broadly comprises a wall mount 602, a support mechanism 604, and a display support 606.

In this embodiment the wall mount 602 further comprises a proximal rotation mechanism 608 substantially at or near its inferior edge. The proximal rotation mechanism 608 supports the proximal end of the support mechanism 604 and can cause the support mechanism 604 to rotate about a substantially horizontal first axis C. In this embodiment, the proximal rotation mechanism 608 is a stepper motor, but in other embodiments the proximal rotation mechanism 608 could be a motor, a linear actuator, or the like. In some embodiments the proximal rotation mechanism may further include a gearbox capable of reducing a drive speed, and increasing a torque, of a motor, such as the stepper motor shown in FIGS. 20 & 21, or the like.

The support mechanism 604 includes a support arm 610 that is fixably disposed at its proximal end on a rotating portion of the proximal rotation mechanism 608. Thus, the proximal rotation mechanism 608 is operable to rotated the support arm 610 from a substantially vertical position, to a substantially horizontal position, and to a downward angled position. In some embodiments, the support mechanism may further include a lift mechanism, such as lift mechanism 36 of FIGS. 1-13.

The display support 606 further includes a distal rotation mechanism 612 substantially at or near its superior edge. The distal rotation mechanism 612 supports the display support 606 at the distal end the support mechanism 604 and can cause the display support 606 to rotate about a substantially horizontal second axis D. The support arm 610 is fixably disposed at its distal end on a rotating portion of the distal rotation mechanism 612. Thus, the distal rotation mechanism can cause the display support 606 to tilt at various angles relative to the wall mount 602 and the support mechanism 604. In this embodiment, the distal rotation mechanism 612 is a stepper motor, but in other embodiments the distal rotation mechanism 612 could be a motor, a linear actuator, or the like. In some embodiments the distal rotation mechanism 612 may further include a gearbox capable of reducing a drive speed, and increasing a torque, of a motor, such as the stepper motor shown in FIGS. 20 & 21, or the like.

In use, the proximal rotation mechanism 608 and distal rotation mechanism 612 each independently rotate to move the display mounting apparatus 600 from a retracted position to an extended position as directed by an electronics system 614, such as electronics system 20 of FIGS. 1-13. Because the proximal rotation mechanism 608 and distal rotation mechanism 612 are independently operable, in some embodiments, the distal rotation mechanism 612 may cause the display support 606 to be generally parallel with the wall mount 602 during the transition from the retracted position to the extended position. In other embodiments, the distal rotation mechanism 612 may cause the display support 606 to be tilted with respect to the wall mount 602 during the transition from the retracted position to the extended position. Once in an extended position, the distal rotation mechanism 612 is operable to tilt the display support 606, and thus any attached display, to nearly any angle.

FIG. 22 illustrates another embodiment of the present invention. This embodiment is substantially similar to the embodiment described with reference to FIGS. 1-13, except as indicated. The display mounting apparatus 700 broadly comprises a wall mount 702, a support mechanism (not shown), a display support 704, and a shroud 706.

The shroud 706 is a tubular enclosure to improve the appearance of the display mounting apparatus 700, to hide the support mechanism, and to reduce any noise created by the display mounting apparatus 700. The shroud 706 is attached at its proximal end to the peripheral edge of the wall mount 702 with fasteners such as buttons, hook-and-loop fasteners, clips, hooks, or the like. The shroud 708 is attached at its distal end to the peripheral edge of the display support 704 with fasteners such as buttons, hook-and-loop fasteners, clips, hooks, or the like. The shroud 708 may be fabric, paper, plastic, elastomeric material, or the like, or combinations thereof. In some embodiments, the shroud 708 may be constructed from pleated layers of cloth and cardboard, like the bellows of an accordion. Thus, the shroud 708 extends easily and folds neatly when the display mounting apparatus 700 is in a retracted position. Additionally, the folded shape of the shroud 708 acts as a baffle to reduce noise caused by motors or actuators. Noise absorbing material may also be used, particularly as a lining of the shroud 708, to further reduce noise.

Although the invention has been described with reference to the preferred embodiment illustrated in the attached drawing figures, it is noted that equivalents may be employed and substitutions made herein without departing from the scope of the invention as recited in the claims.

What is claimed is:

1. A display mounting apparatus comprising:
a wall mount;
a support mechanism including—
an upper support arm rotatably connected to the wall mount about a substantially horizontal axis at a proximal end of the upper support arm,
a lower support arm rotatably connected to the wall mount about a substantially horizontal axis at a proximal end of the lower support arm;
a lift mechanism connected at a first end to the upper support arm and connected at a second end to the wall mount; and
a display support rotatably connected to a distal end of the upper support arm about a substantially horizontal axis and rotatably connected to a distal end of the lower support arm about a substantially horizontal axis,
wherein the display support is operable to move from a retracted position to an extended position and wherein the display support is operable to support a display weighing 11.3 kg or more.

2. The display mounting apparatus of claim 1, wherein the lift mechanism is selected from the group consisting of an air spring, air spring, an extension spring, a safety drawbar spring, a torsion spring, and a polymeric band.

3. The display mounting apparatus of claim 1, further comprising:
an actuator connected at a first end to the upper support arm and connected a second end to the lower support arm; and
an electronics system in electronic communication with the actuator.

4. The display mounting apparatus of claim 3 wherein the actuator is an electro-mechanical linear actuator, a stepper motor, a servo motor, a DC motor, an AC motor, and a universal motor.

5. The display mounting apparatus of claim 3, wherein the electronics system further comprises:
an electronic signal-receiving device;
an electronic processor; and
an electronic position-sensing device.

6. The display mounting apparatus of claim 5, wherein the electronic signal-receiving device is selected from the group consisting of: an infrared receiver, an ethernet port, a radio frequency receiver, a BlueTooth receiver, an 802.11 receiver, a digital signal processor, a voltage-pulse sensing circuit, a voltage-level sensing circuit, and a current-sensing circuit.

7. The display mounting apparatus of claim 5, wherein the electronic position-sensing device is selected from the group consisting of an accelerometer, a reed switch, a force sensor, a mechanical switch, a potentiometer, a rotary position sensor, a rotary encoder, a capacitive sensor, an optical encoder, an ultrasonic rangefinder, and a flex sensor.

8. The display mounting apparatus of claim 1, further comprising:
a tubular shroud removably connected at its proximal end to the wall mount and removably connected at its distal end to the display support.

9. The display mounting apparatus of claim 1, wherein the support mechanism further comprises:
a folding support arm rotatably connected at its proximal end to the wall mount and rotatably connected at its distal end to the upper support arm.

10. The display mounting apparatus of claim 1, further comprising:
a rotating mechanism including—
a base disposed on the display support,
a rotating plate pivotally connected to the base an operable to rotate about a substantially horizontal axis.

11. The display mounting apparatus of claim 1, further comprising:
a rotating mechanism including—
a base disposed on the display support,
a rotating plate pivotally connected to the base an operable to rotate about a substantially vertical axis.

12. The display mounting apparatus of claim 1, further comprising:
a latch disposed on the display mount, and
a latch receiver disposed on the wall mount,
wherein the latch is operable to matingly engage the latch receiver when the display mounting apparatus is in a retracted position.

13. A display mounting apparatus comprising:
a wall mount including a proximal rotation device disposed thereon, the proximal rotation device including a fixed body and a rotating portion;
a support mechanism;
a display support including a distal rotation device disposed thereon, the distal rotation device including a fixed body and a rotating portion; and
an electronics system in electrical communication with the proximal rotation device and the distal rotation device,
wherein the support mechanism fixedly disposed at a proximal end on the rotating portion of the proximal rotation device, and the support mechanism fixedly disposed at a distal end on the rotating portion of the distal rotation device.

14. The display mounting apparatus of claim 13, wherein the proximal rotation device is selected from the group consisting of a stepper motor, a electromechanical linear actuator, a servo motor, a DC motor, an AC motor, and a universal motor.

15. The display mounting apparatus of claim 13, further comprising a lift mechanism connected to the support mechanism at a first end and connected to the wall mount at a second end.

16. The display mounting apparatus of claim 13, wherein the electronics system further comprises:
an electronic signal-receiving device;
an electronic processor; and
an electronic position-sensing device.

17. The display mounting apparatus of claim 13, further comprising:
a tubular shroud removably connected at its proximal end to the wall mount and removably connected at its distal end to the display support.

18. The display mounting apparatus of claim 13, further comprising:
a rotating mechanism including—
a base disposed on the display support,
a rotating plate pivotally connected to the base an operable to rotate about a substantially vertical axis.

19. The display mounting apparatus of claim 16, wherein the electronic position-sensing device is selected from the group consisting of an accelerometer, a reed switch, a force sensor, a mechanical switch, a rotary position sensor, a rotary encoder, a capacitive sensor, an optical encoder, an ultrasonic rangefinder, and a flex sensor.

20. A display mounting apparatus comprising:
a wall mount;
a support mechanism including—
an upper support arm rotatably connected to the wall mount about a substantially horizontal axis at a proximal end of the upper support arm,
a lower support arm rotatably connected to the wall mount about a substantially horizontal axis at a proximal end of the lower support arm;
a lift mechanism connected at a first end to the upper support arm and connected at a second end to the wall mount;
an actuator connected at a first end to the upper support arm and connected a second end to the lower support arm;
a display support rotatably connected to a distal end of the upper support arm about a substantially horizontal axis and rotatably connected to a distal end of the lower support arm about a substantially horizontal axis; and
an electronics system in electronic communication with the actuator and including—
an electronic signal-receiving device;
an electronic processor; and
an electronic position-sensing device,
wherein the actuator is operable to move the display support from a retracted position to an extended position.
